(19) United States
(12) Patent Application Publication
(10) Pub. No.: US 2025/0054721 A1
(43) Pub. Date: Feb. 13, 2025

(54) IN-LINE ELECTRON BEAM INSPECTION METHOD FOR SEMICONDUCTOR PROCESSES AND COLD FIELD EMITTER WITH NANOMETER-SCALE PROTRUSION STRUCTURE FOR IN-LINE ELECTRON BEAM INSPECTION EQUIPMENT APPLIED TO SEMICONDUCTOR PROCESSES AND MANUFACTURE METHOD THEREOF

(71) Applicant: ALES TECH INC., Kaohsiung City (TW)

(72) Inventors: Wei-Tse Chang, Taoyuan City (TW); Chun-Yueh Lin, Keelung City (TW)

(21) Appl. No.: 18/792,942

(22) Filed: Aug. 2, 2024

(30) Foreign Application Priority Data
Aug. 7, 2023 (TW) 112129629

(51) Int. Cl. H01J 37/073; H01J 1/304; H01J 9/02

(52) U.S. Cl. CPC H01J 37/073; H01J 1/3044; H01J 9/025; H01J 2237/06341

(57) ABSTRACT

The present invention discloses an in-line electron beam inspection method for semiconductor processes, an in-line electron beam inspection equipment having a cold field emitter with a nanometer-scale protrusion structure applied to semiconductor processes and a manufacture method thereof. The in-line electron beam inspection equipment having a cold field emitter with a nanometer-scale protrusion structure comprises a tip end part and a nanometer-scale protrusion structure. The tip end part is formed in a front end of an emitter. The nanometer-scale protrusion structure is formed on a surface of the tip end part. The nanometer-scale protrusion structure is an atomic stacking structure. The cold field emitter is operated in the vacuum environment below 3×10⁻⁹ millibar.

### CROSS-REFERENCE TO RELATED APPLICATION(S)

This application claims the priority benefit of TW application serial No. 112129629 filed on Aug. 7, 2023, the entirety of which is hereby incorporated by reference herein and made a part of specification.

### BACKGROUND OF THE INVENTION

### 1. Field of the Invention

The invention is related to a cold field emitter with a nanometer-scale protrusion structure and a manufacture method thereof, particularly to an in-line electron beam inspection equipment having a cold field emitter with a nanometer-scale protrusion structure applied to semiconductor processes and a manufacture method thereof.

### 2. Description of the Related Art

Refer to FIG. 2A and FIG. 2B. FIG. 2A and FIG. 2B are the schematic diagram and the enlarged schematic diagram of a tip end part of an emitter 2 for the prior art utilizing the emitter to emit electron sources for electron beam inspection (e-beam inspection; EBI). The method of the electron beam inspection utilizes the emitter 2 with a tip end structure to emit an electron beam to inspect defects of the semiconductor devices. As a result, the method is enabling real-time in-line inspection of the defects of the semiconductor devices by e-beam inspection.

Refer to FIG. 3A and FIG. 3B. FIG. 3A is the usage state schematic diagram for the prior art using the emitter with the tip end structure after a period of operation. FIG. 3B is the enlarged schematic diagram for the tip end surface of the emitter of the prior art contaminated by gas molecules and pollution. The e-beam inspection utilizes the emitter 2 with the tip end structure to emit electron beams in the vacuum environment to inspect defects of the semiconductor devices. Although the emitter 2 is operated in the vacuum environment, a part of gas molecules and pollution D exist in the vacuum operation environment. After a period of operation, gas molecules and pollution D collide and accumulate on the tip end 21 surface of the emitter 2 with the tip end structure. Even only one single atom is accumulated on the tip end 21 surface of the emitter 2, the work function of the emitter surface is varied, the emission of the electron is changed, the electron beam current is unstable, the period, the performance, and the stability of the electron beam emitted by the emitter and the accuracy of the e-beam inspection are affected. Moreover, as shown in FIG. 3B, the electron beam emitted by the emitter 2 with the tip end structure occupies a huge area of the tip end 21 surface. Generally speaking, a radius of curvature of the tip end of the emitter 2 is approximately between 50 and 200 nanometers. An emission area of the emitter 2 is about ten thousand square nanometers to two hundred-fifty thousand square nanometers. Under this condition, gas molecules and pollution D easily collide and accumulate on the tip end 21 surface of the emitter 2 with the tip end structure.

To solve the above problem, the conventional method is to stop the operation of the cold field electron source and clean the surface of the emitter 2 with the tip end structure. As shown in FIG. 3A, the electron beam current goes through a decrease period, a stable period, and an unstable period over the whole operation period. In a normal condition, the cold field electron source is operated at the stable period. Therefore, after a period of operation, gas molecules and pollution D collide and accumulate on the tip end 21 surface of the emitter 2 with the tip end structure. When the electron beam current generated by the emitter 2 with the tip end structure is affected, the operation of the cold field electron source needs to be stopped and the emitter 2 needs to be cleaned. The present cold field electron source needs to be cleaned every 8 to 12 hours, particularly the tip end part of the cold field electron source. Therefore, the cold field electron source must stop operation. In this way, the overall production capacity and efficiency of the semiconductor processes are significantly affected.

Moreover, another method is to increase the vacuum level of the vacuum operation environment of the cold field electron source. The method is to increase the vacuum level to under 1×10⁻¹¹ millibar, an extreme high vacuum (XHV) environment, for diminishing gas molecules and pollution D in the operation environment. After a period of operation, even the cold field electron source is manipulated at the XHV environment, gas molecules and pollution D are accumulated on the surface of the emitter surface. Contrary to above method for stopping the manipulation of the cold field electron source, the method for increasing the vacuum level can extend the operation period without cleaning the surface of the emitter but the method needs to provide a strict vacuum operation environment and to disburse a higher cost for the equipment. Consequently, although the conventional cold field electron source has advantages comprising a high brightness, a high resolution, and so on, the present cold field electron source fails to be widely applied to an in-line e-beam inspection equipment in semiconductor processes.

Accordingly, how to provide an improved method and structure is an urgent subject to tackle.

### SUMMARY OF THE INVENTION

In view of this, the present invention provides an in-line e-beam inspection equipment having a cold field emitter with a nanometer-scale protrusion structure applied to semiconductor processes. The e-beam inspection equipment having a cold field emitter with a nanometer-scale protrusion structure comprises a tip end part and a nanometer-scale protrusion structure. The tip end part is formed in a front end of an emitter. The nanometer-scale protrusion structure is formed on a surface of the tip end part. The nanometer-scale protrusion structure is an atomic stacking structure. The cold field emitter is operated in a vacuum environment of 1×10⁻¹² millibar to 3×10⁻⁹ millibar. The nanometer-scale protrusion structure has a protrusion radius of curvature less than one-third of the radius of curvature of the tip end part.

The invention further discloses an in-line e-beam inspection method for semiconductor processes, which utilizes the e-beam inspection equipment having the cold field emitter with a nanometer-scale protrusion structure mentioned above. The cold field emitter is operated in a vacuum environment of 1×10⁻¹² millibar to 3×10⁻⁹ millibar. The method comprises steps as follows: providing an emitter with a nanometer-scale protrusion structure; applying an operating voltage to the emitter with the nanometer-scale protrusion structure; and after a predetermined operation period, cleaning a tip end part surface of the emitter with the nanometer-scale protrusion structure, and applying the operating voltage to the emitter with the nanometer-scale protrusion structure; wherein the predetermined operation period ranges from 48 to 4500 hours. In an embodiment of the invention, the operating voltage is between 100 and 30000 volts. An extraction voltage of the electron beam is between 100 and 10000 volts.

The invention further discloses a method for manufacturing a cold field emitter with a nanometer-scale protrusion structure. A nanometer-scale protrusion structure is formed on a tip end part surface of the emitter. The nanometer-scale protrusion structure has a protrusion radius of curvature. The protrusion radius of curvature is less than one-third of the radius of curvature of the tip end part.

As mentioned above, the cold field emitter with a nanometer-scale protrusion structure manufactured by the method of the invention has the advantages including high brightness, extended operation period, improved performance, enhanced resolution and faster scanning speed. The high brightness facilitates high-speed imaging and high-resolution imaging. Since the emission area of the nanometer-scale protrusion structure is tiny, the probability for pollution and gas molecules contaminating the emission area is reduced. Accordingly, the operation period for the cold field emitter can be extended, the inspection performance can be upgraded, and can be further widely and stably applied to in-line e-beam inspection in the semiconductor processes.

### BRIEF DESCRIPTION OF THE DRAWINGS

FIG. 1A and FIG. 1B are the schematic diagram and the enlarged diagram of the in-line electron beam inspection equipment having the cold field emitter with a nanometer-scale protrusion structure applied to the semiconductor processes;

FIG. 1C is the enlarged schematic diagram of the tip end surface of the emitter with nanometer-scale protrusion structure contaminated by gas molecules and pollution;

FIG. 1D is the operation environment schematic diagram of the in-line electron beam inspection in the semiconductor processes;

FIG. 2A and FIG. 2B are the schematic diagram and the enlarged schematic diagram of the tip end part of the emitter for the prior art utilizing the emitter to emit electron sources for electron beam inspection;

FIG. 3A is the usage state schematic diagram for the prior art using the emitter with the tip end structure after a period of operation; and

FIG. 3B is the enlarged schematic diagram for the tip end surface of the emitter of the prior art contaminated by gas molecules and pollution.

### DETAILED DESCRIPTION OF THE INVENTION

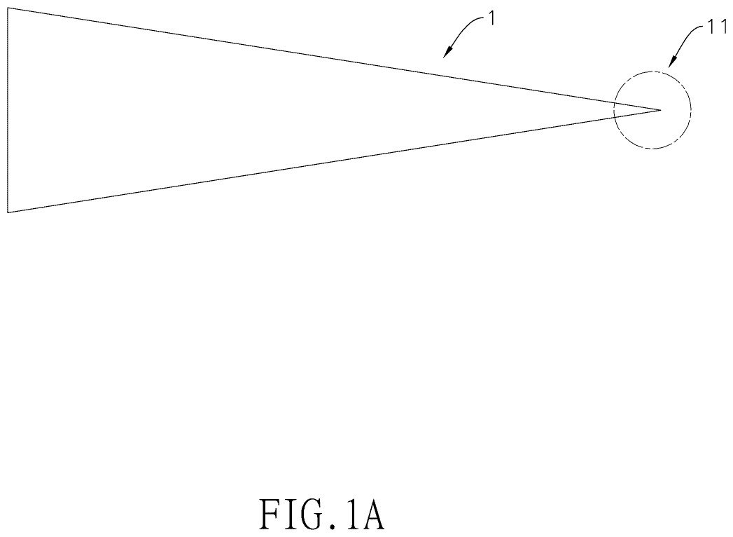

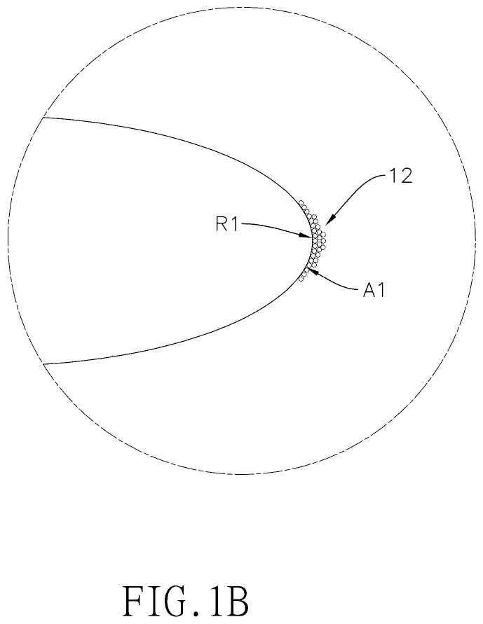

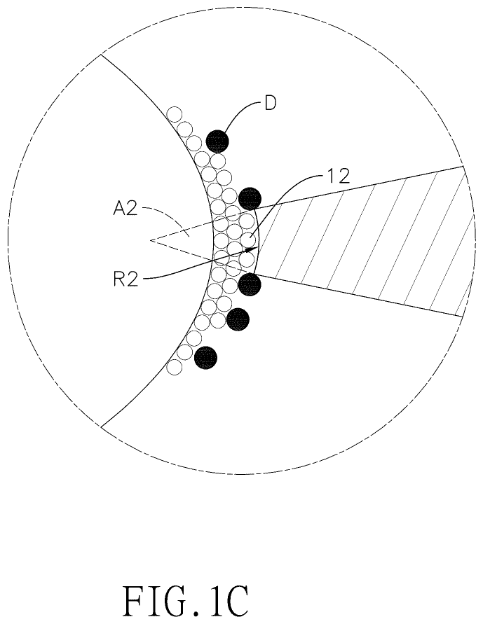

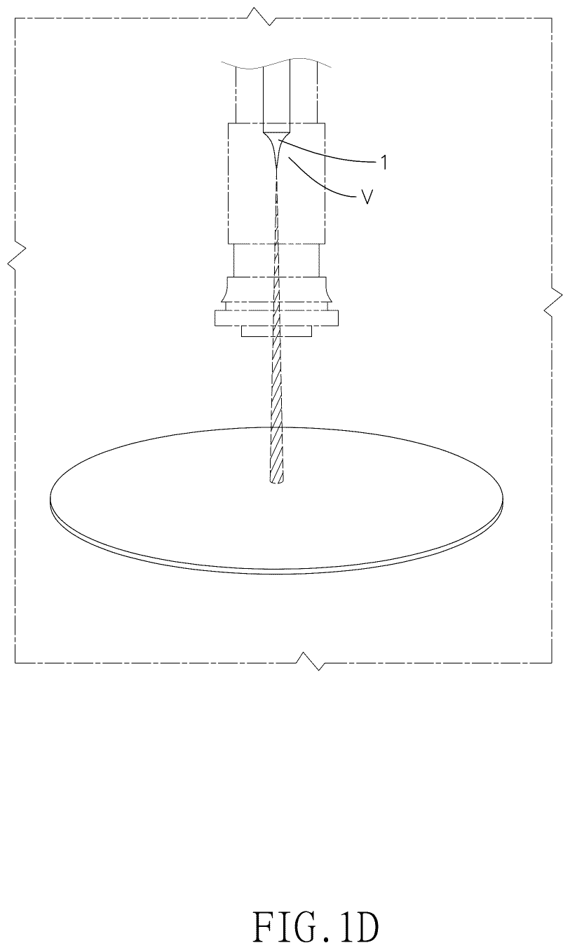

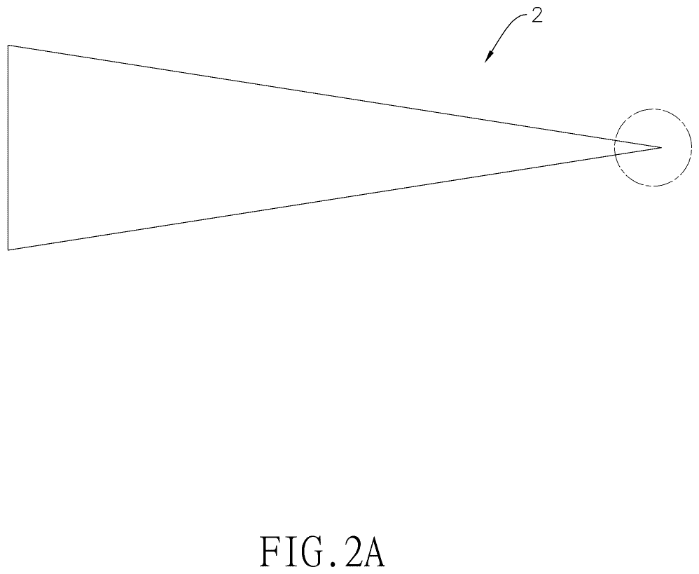

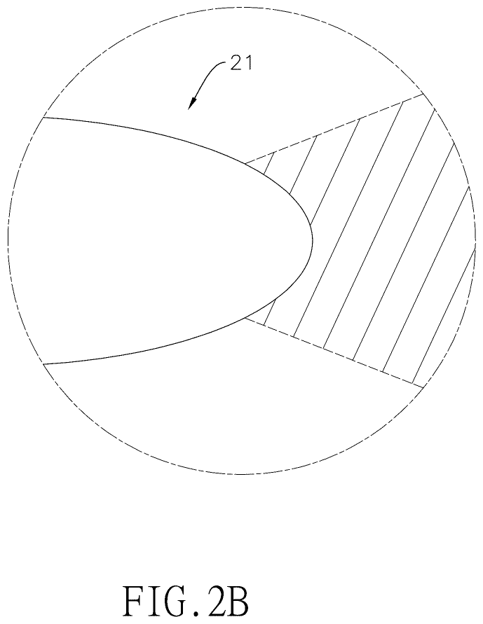

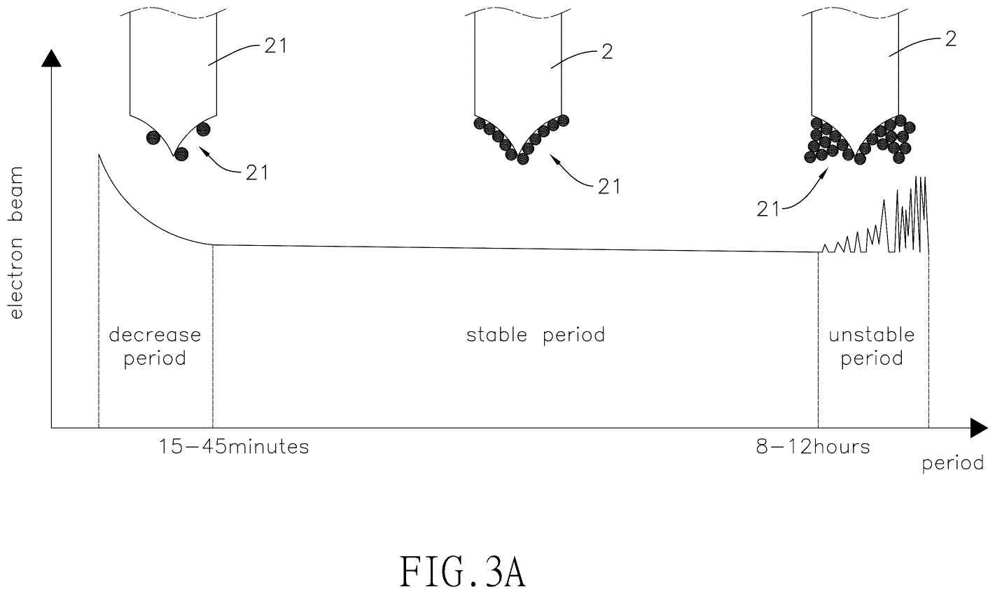

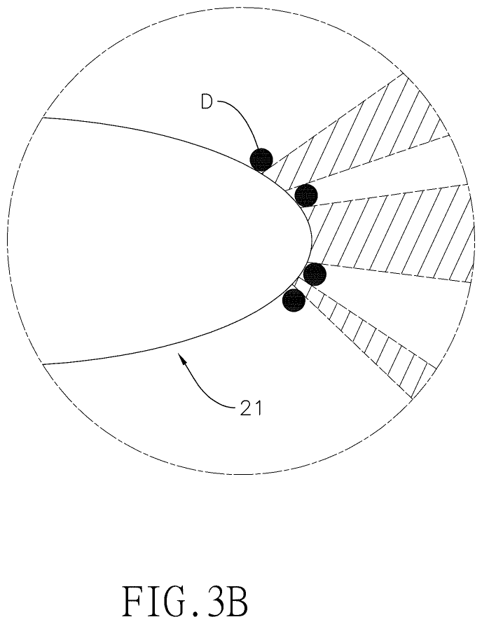

Refer to FIG. 1A to FIG. 1C. FIG. 1A and FIG. 1B are the schematic diagram and the enlarged diagram of the in-line electron beam inspection equipment having the cold field emitter with a nanometer-scale protrusion structure applied to the semiconductor processes. FIG. 1C is the enlarged schematic diagram of the tip end surface of the emitter with nanometer-scale protrusion structure contaminated by gas molecules and pollution. The emitter 1 comprises a tip end part 11 and a nanometer-scale protrusion structure 12. The tip end part 11 is formed in a front end of the emitter 1. The nanometer-scale protrusion structure 12 is formed on a surface of the tip end part 11. The nanometer-scale protrusion structure 12 is an atomic stacking structure. The cold field emitter is operated in a vacuum environment of 1×10⁻¹² millibar to a 3×10⁻⁹ millibar. The nanometer-scale protrusion structure 12 has a protrusion radius of curvature R2 (as shown in FIG. 1C). The protrusion radius of curvature R2 is less than one-third of the radius of curvature R1 of the tip end part 11 (as shown in FIG. 1B). In an embodiment of the invention, the radius of curvature R1 of the tip end part 11 of the emitter 1 is approximately between 50 and 200 nanometers. In addition, the protrusion radius of curvature R2 is less than 3 nanometers. In an embodiment, the minimum protrusion radius of curvature R2 is 0.3 nanometer as a diameter of an atom. Furthermore, in an embodiment of the invention, the radius of curvature of the nanometer-scale protrusion structure 12 is between 0.2 and 3 nanometers. The emission area of the nanometer-scale protrusion structure 12 is between 0.25 and 60 square nanometers.

Refer to FIG. 1C and FIG. 1D. FIG. 1D is the operation environment schematic diagram of the in-line electron beam inspection in the semiconductor processes. As shown in FIG. 1C and FIG. 1D, the emitter tip end part 11 on the surface of the nanometer-scale protrusion structure 12 is an atomic stacking structure. The atomic stacking structure has an extremely tiny area. Accordingly, even the cold field emitter is operated after a period of operation period, the probability for gas molecules and pollution D contaminating the nanometer-scale protrusion structure 12 is significantly reduced. Therefore, the emitter with the nanometer-scale protrusion structure is used in the operation environment of the cold field electron source, which is the vacuum environment V ranging from 1×10⁻¹² millibar to 3×10⁻⁹ millibar, and the operation period can be extended before the emitter surface needs to be cleaned.

The invention further discloses a method for manufacturing a cold field emitter with a nanometer-scale protrusion structure. The method is to form a nanometer-scale protrusion structure 12 on the surface of the tip end part of the emitter. The nanometer-scale protrusion structure 12 has a protrusion radius of curvature R2. The protrusion radius of curvature R2 is less than one-third of the radius of curvature R1 of the tip end part 11. In the invention, the method for manufacturing the nanometer-scale protrusion structure 12 may include the below embodiments but is not limited thereto.

In an embodiment of the invention, the nanometer-scale protrusion structure 12 is formed in the vacuum environment with a great electric field. The value of the electric field is between 4V/Å and 10V/Å.

In an embodiment of the invention, the nanometer-scale protrusion structure is formed in the vacuum environment with a great electric field and is further heated at a predetermined temperature. The predetermined temperature is at a centigrade temperature between 600 and 1500 degrees Celsius.

In an embodiment of the invention, the nanometer-scale protrusion structure 12 is formed by being exposed in the vacuum environment with nitrogen and by applying the great electric field.

In an embodiment of the invention, the nanometer-scale protrusion structure 12 is formed by being exposed in the vacuum environment with oxygen, being heated and by faceting, that is, forming a pyramidal structure on the tip end part surface of the emitter; wherein the heated temperature is between 900 and 1600 Kelvin.

In an embodiment of the invention, the nanometer-scale protrusion structure 12 is formed by electroplating or vacuum depositing a noble metal (such as gold, palladium, platinum, rhodium, or iridium) onto a tip end part surface of the emitter, followed by heating and faceting, that is, forming a pyramidal structure on the tip end part surface of the emitter; wherein the heated temperature is between 900 and 1600 Kelvin.

In an embodiment of the invention, the nanometer-scale protrusion structure 12 is formed by the ion bombardment in the vacuum environment.

As mentioned above, contrary to either thousands or tens of thousands of atoms on the emission area of the tip end surface of the emitter 1, the nanometer-scale protrusion structure 12 formed on the tip end surface of the emitter 1 by aforementioned embodiments is an atomic stack as shown in FIG. 1B. That is, each atom stacks and protrudes on the tip end surface of the emitter 1 to form the atomic stacking protrusion structure. By the structure, the electron beam emitted by the emitter 1 is more centralized. In addition, as shown in FIG. 1B and FIG. 1C, since the emission area A2 of the nanometer-scale protrusion structure is less than one-ninth the size of the emission area A1 on the tip end surface of the emitter 1, the probability for pollution and gas molecules in the vacuum environment contaminating the nanometer-scale protrusion structure is reduced to less than one-ninth of the original. As a result, the period without cleaning the emitter 1 can be extended beyond nine times. That is, the cold field emitter only requires to be cleaned after the predetermined operation period ranging from 48 hours to 4500 hours. In another embodiment, the predetermined operation period is between 48 and 720 hours. Furthermore, in an embodiment of the invention, the area of the emission area A1 is between 160 square nanometers and 25 ten thousand square nanometers. The emission area A2 is between 0.25 and 60 square nanometers.

The invention further discloses an in-line electron beam inspection method for semiconductor processes. The method is operating the cold field electron source in the vacuum environment of 1×10⁻¹² millibar to 3×10⁻⁹ millibar, comprising steps as follows: in step S11, providing the aforementioned emitter with the nanometer-scale protrusion structure; in step S12, applying an operating voltage to the emitter with the nanometer-scale protrusion structure; in step S13, after a predetermined operation period, cleaning the tip end part surface of the emitter with the nanometer-scale protrusion structure, and continuing the in-line e-beam inspection in the semiconductor processes; wherein the predetermined operation period is between 48 and 4500 hours. In another embodiment, the predetermined operation period is between 48 and 720 hours. In addition, in an embodiment of the invention, an extraction voltage of the electron beam is between 100 and 10000 volts. The operating voltage is between 100 and 30000 volts.

Moreover, the brightness of the electron beam generated by a general cold field emitter is approximately between 10¹² and 10¹³ A/m². Sᵣ. In contrast, in an embodiment of the invention, the brightness of the electron beam generated by the cold field emitter with the nanometer-scale protrusion structure is approximately between 10¹³ A/m². Sᵣ and 10¹⁶ A/m². Sᵣ.

In summary, the cold field emitter with a nanometer-scale protrusion structure manufactured by the method of the invention has the advantages comprising high brightness, extended operation period, improved performance, enhanced resolution and faster scanning speed. The high brightness facilitates high-speed imaging and high-resolution imaging. Since the emission area of the nanometer-scale protrusion structure is tiny, the probability for pollution and gas molecules contaminating the emission area is reduced. Accordingly, the operation period for the cold field emitter can be extended, the inspection performance can be upgraded, and can be further widely and stably applied to in-line e-beam inspection in the semiconductor processes.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. An in-line electron beam inspection equipment having a cold field emitter with a nanometer-scale protrusion structure applied to semiconductor processes, comprising:
a tip end part, formed in a front end of an emitter; and
a nanometer-scale protrusion structure, formed on a surface of the tip end part;
wherein the nanometer-scale protrusion structure is an atomic stacking structure;
wherein the cold field emitter is operated in a vacuum environment of 1×10⁻¹² millibar to 3×10⁻⁹ millibar;
wherein the nanometer-scale protrusion structure has a protrusion radius of curvature, the protrusion radius of curvature is less than one-third of a radius of curvature of the tip end part.

2. The in-line electron beam inspection equipment having the cold field emitter with the nanometer-scale protrusion structure applied to the semiconductor processes as claimed in claim 1, wherein an emission area of the nanometer-scale protrusion structure is less than one-ninth the size of an emission area on the tip end surface of the emitter.

3. An in-line electron beam inspection method for semiconductor processes, utilizing the in-line electron beam inspection equipment having the cold field emitter with the nanometer-scale protrusion structure as claimed in claim 1, comprising steps as follows:
applying an operating voltage to the emitter with the nanometer-scale protrusion structure; and
after a predetermined operation period, cleaning a tip end part surface of the emitter with the nanometer-scale protrusion structure;
wherein the predetermined operation period is between 48 and 4500 hours.

4. A method for manufacturing a cold field emitter with a nanometer-scale protrusion structure, forming a nanometer-scale protrusion structure on a tip end part surface of an emitter;
wherein the nanometer-scale protrusion structure has a protrusion radius of curvature, and the protrusion radius of curvature is less than one-third of a radius of curvature of the tip end part.

5. The method for manufacturing the cold field emitter with a nanometer-scale protrusion structure as claimed in claim 4, wherein the nanometer-scale protrusion structure is formed in a vacuum environment with an electric field; the electric field is between 4V/Å and 10V/Å.

6. The method for manufacturing the cold field emitter with a nanometer-scale protrusion structure as claimed in claim 5, wherein the nanometer-scale protrusion structure is formed in the vacuum environment with the electric field and is further heated at a predetermined temperature; the predetermined temperature is at a centigrade temperature between 600 and 1500 degrees Celsius.

7. The method for manufacturing the cold field emitter with a nanometer-scale protrusion structure as claimed in claim 4, wherein the nanometer-scale protrusion structure is formed by an ion bombardment in a vacuum environment.

8. The method for manufacturing the cold field emitter with a nanometer-scale protrusion structure as claimed in claim 4, wherein the nanometer-scale protrusion structure is formed in a vacuum environment with nitrogen and by applying an electric field.

9. The method for manufacturing the cold field emitter with a nanometer-scale protrusion structure as claimed in claim 4, wherein the nanometer-scale protrusion structure is formed by being exposed in a vacuum with oxygen and being heated to form a faceting structure on the tip end part surface of the emitter.

10. The method for manufacturing the cold field emitter with a nanometer-scale protrusion structure as claimed in claim 4, wherein the nanometer-scale protrusion structure is formed by electroplating or vacuum depositing a noble metal on a tip end part surface of the emitter and being heated to form a faceting structure on the tip end part surface of the emitter.
